(19) United States
(12) Patent Application Publication
(10) Pub. No.: US 2008/0306700 A1
(43) Pub. Date: Dec. 11, 2008

(54) Photvoltaic solar array health monitor

(75) Inventors: Elias Anthony Kawam, Phoenix, AZ (US); Elisa Anne Kawam, Tempe, AZ (US)

Correspondence Address: Edward J Mischen, 4400 E. Ridgewood Lane, Gilbert, AZ, 85297, US

(73) Assignee: Ekla-Tek L.L.C

(21) Appl. No.: 12/156,935

(22) Filed: Jun. 5, 2008

Related U.S. Application Data
(60) Provisional application No. 60/933,488, filed on Jun. 7, 2007.

(51) Int. Cl. G01R 19/00; G06F 15/00

(52) U.S. Cl. 702/64; 702/182

(57) ABSTRACT

An integrated photovoltaic (PV) solar array health monitor configured to derive informations relating to the health of a string of PV solar cells. A transmit module 300 switches from a normal mode of operation and to a self-powered monitoring mode of operation and provides a load 318 to the solar cell string. Processor/control logic 308 directs activities of the monitoring process to obtain informations relating to the solar cell string. The informations are converted to a suitable format for transmission at an antenna 336, via a transmitter circuit 316. The transmitted information reflects the health status of the solar cell string.

### CROSS-REFERENCE TO RELATED APPLICATIONS

This application claims priority under 35 U.S.C. §119(e) from U.S. provisional application Ser. No. 60/933,488 filed Jun. 7, 2007.

### BACKGROUND OF THE INVENTION

The present invention relates to monitoring the health of a photovoltaic solar array. Specifically, a modular electronic data acquisition system is used to acquire the voltage and current readings from cells or strings of cells or entire photovoltaic solar arrays.

The success of photovoltaic (PV) solar cell power generation depends greatly upon maintaining highly efficient performance from PV cells which comprise the PV array.

A number of factors affect the performance of PV solar cells in a PV solar array. Such factors include, for example, cell exposure to ionizing radiation, integrity of cell interconnects, quality of cell interconnect materials, exposure to electrostatic discharge (ESD), exposure to temperature variations, doping levels of glass used to protectively coat the cell, and manufacturing component choices and variations.

For optimum performance of the PV solar array, the relation of solar cell performance to the aforementioned factors must be well understood and correlated. To assure optimum performance, PV cells, cell strings, or an entire array are periodically loaded and shorted to generate current-voltage (I-V) characteristics indicative of their health status and power generating ability. The resultant I-V characteristics are then compared to determine the status of system deterioration.

For terrestrial applications, methods are presently used to selectively load and short the photovoltaic (PV) cells, cell strings, and arrays to obtain characteristic I-V curves for the PV cells. This process is time consuming, laborious, and when field installed, requires extensive instrumentation modifications.

For extra-terrestrial applications, present technology is limited in application to the laboratory, using the same techniques as used in terrestrial applications or using custom circuitry that requires extensive system design and accommodation to acquire PV cell voltages and currents. Moreover, additional power supplies are required to power the custom circuitry.

Furthermore, the American Institute of Aeronautics and Astronautics (AIM) publicly released a standard pertaining to Spacecraft Electrical Power Systems—S-122-2007 through the AIAA website. Paragraph 5.2.11.3 of the standard requires spacecraft contractors to set-aside 0.3% of all required solar cells on the solar array to be used as “monitor” cells, such that the monitor cells be used to analyze and predict the health and power generation capability of the entire array. For extra-terrestrial applications, the demand for PV solar cell monitoring is extremely critical, and methods do not presently exist to facilitate the requirement.

Hence, there is truly a need for both terrestrial and extra-terrestrial applications for a self powering, highly efficient minimum component, highly automated, and highly accurate system to precisely predict the health of solar photovoltaic arrays.

### BRIEF DESCRIPTION OF THE DRAWINGS

FIG. 1 illustrates a wireless connection implementation block diagram of the present invention

FIG. 2 illustrates a typical solar photovoltaic cell I-V characteristic curve.

FIG. 3 illustrates a solar photovoltaic in-situ single string embodiment of the present invention.

FIG. 3a illustrates a representative load circuit detail for the embodiment of FIG. 3.

FIG. 4 illustrates a solar photovoltaic in-situ multiple string embodiment of the present invention.

FIG. 5 illustrates a single package module implementation for the present invention.

FIG. 5a illustrates a circuit implementation for the single package module implementation of FIG. 5 for the present invention.

### SUMMARY OF THE INVENTION

Accordingly, it is the object of the present invention to provide a system for monitoring the health of a photovoltaic (PV) solar array.

It is another object of the present invention to provide an in-situ solar PV health monitor transmitter without the need for external connections.

It is yet another object of the present invention to continuously and remotely monitor the voltage, temperature, and current status of a terrestrial or an extra-terrestrial based photovoltaic (PV) solar array.

It is a further object of the present invention to provide operational power from the monitored cells within the array or the monitor strings within the array or the array itself, to perform the health monitoring function.

It is a still a further object of the present invention to provide a self-powered, stand alone packaged module incorporating the present invention.

More generally, the present invention is a system for monitoring the health of a photovoltaic (PV) solar array that incorporates an efficient method of switching power within the array to accommodate the monitoring of a cell string or single cell, or the monitoring of one of a plurality of cell strings within the array, or the monitoring of the entire array.

The present invention processes power generated by a PV solar panel, string, cell, or array and subsequently uses the PV panel, string, cell, or array as a test article to monitor and determine the health status of the same PV panel or string.

The PV health monitor system applies progressively greater loads to the solar PV panel, cell, or array, or string to be monitored, and the system acquires temperature information and acquires corresponding voltage and current information for specific loading conditions. The current (load condition) and voltage information, i.e., I-V information, is digitized and the resultant information is transmitted to a compatible receiver using wired or wireless means. The information is monitored at, for example, a receiving data bank (not shown), for variations from previous characteristic collections to determine if the health of the PV panel or string has deviated from a prior condition.

Operating power for the monitoring system is derived from the PV cell, panel, string, or array, i.e., the PV solar device and stored in a storage element, for example, a capacitor or rechargeable battery. The PV solar device is then disconnected from the power storage system and connected to an internal active load while the monitoring system progressively loads the PV solar device to acquire progressively greater amounts of load current. Information is collected ranging from Voc (open circuit), i.e., virtually no load current, to Isc, (virtual short circuit) zero voltage condition to indicate relative health of the solar panel or string.

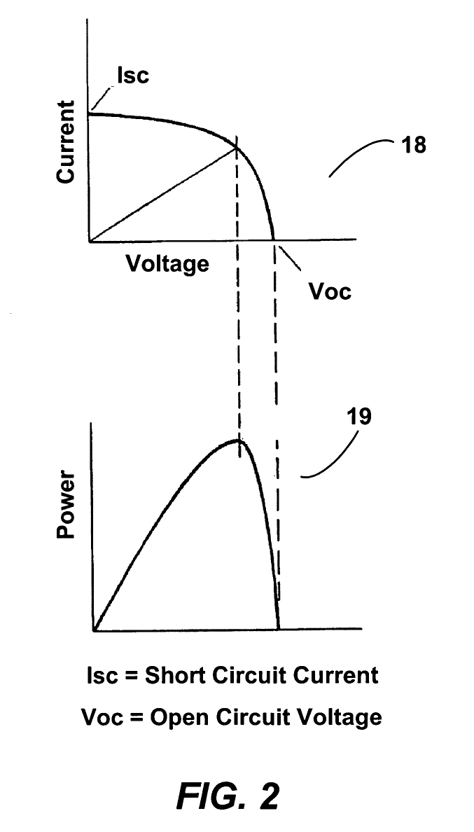

The current-voltage information is used to generate an I-V curve similar to that of FIG. 2. The information would be used periodically over the life of the system to compare the health and degradation of the system, over time, to a baseline information set.

### DETAILED DESCRIPTION OF THE DRAWINGS

The present invention is a photovoltaic (PV) solar array health monitoring system suitable for use in a number of applications including terrestrial and extra-terrestrial installations.

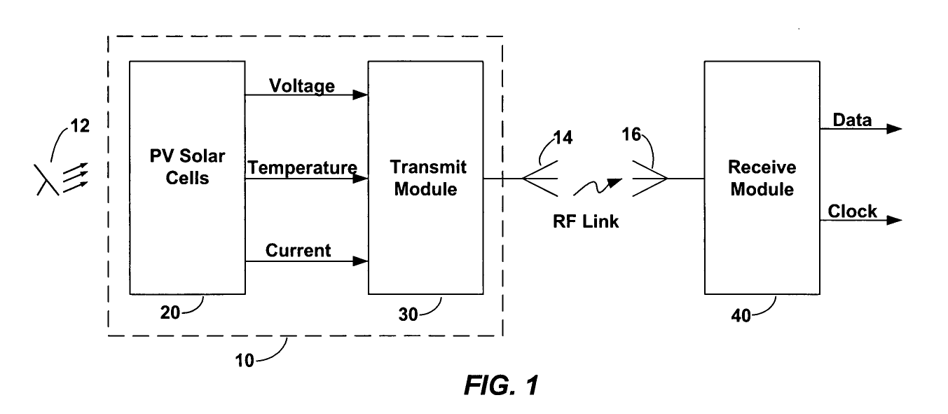

Looking at FIG. 1, a block diagram incorporating the present invention is shown. Photovoltaic (PV) solar cells 20 and transmit module 30 are mounted on solar panel 10. PV solar cells 20 form a solar panel, cell, string, or array configured to receive photon energy from light source 12 thus generating power for use by transmit module 30 and for other functions (not shown) incorporated into the terrestrial or extra-terrestrial application.

Transmit module 30 communicates with PV solar cells 20 to command power routing within the PV solar cell array and to address the portion of the cells to be monitored for health status. PV solar health monitoring information is coupled from PV solar cells 20, respectively, to transmit module 30 via voltage, temperature, and current signal connections.

Transmit module 30 communicates module output information from transmit antenna 14 via radio frequency (RF) link to receive antenna 16. Receive antenna 16 is coupled to the input of receive module 40. Alternatively, as one skilled in the art would recognize, the radio frequency link is also a hard wired link, a magnetic link, a sonic link, or an optically coupled link.

Receive module 40 next communicates the information and an internal clock signal, for data synchronization, to a system data collection bank (not shown) for analysis of the health status of a portion of PV solar cells 20.

Referring now to FIG. 2, curves representative of the health status of a PV solar panel are shown as I-V curve 18 and power curve 19. Circuits suitable for obtaining the specific voltage and current readings from a PV panel using either linear or non-linear means are known in the art. For example, power MOSFETs under step control of the gate voltage provide a suitable method to control the PV array from an open circuit (Voc) condition to short circuit current (Isc) condition.

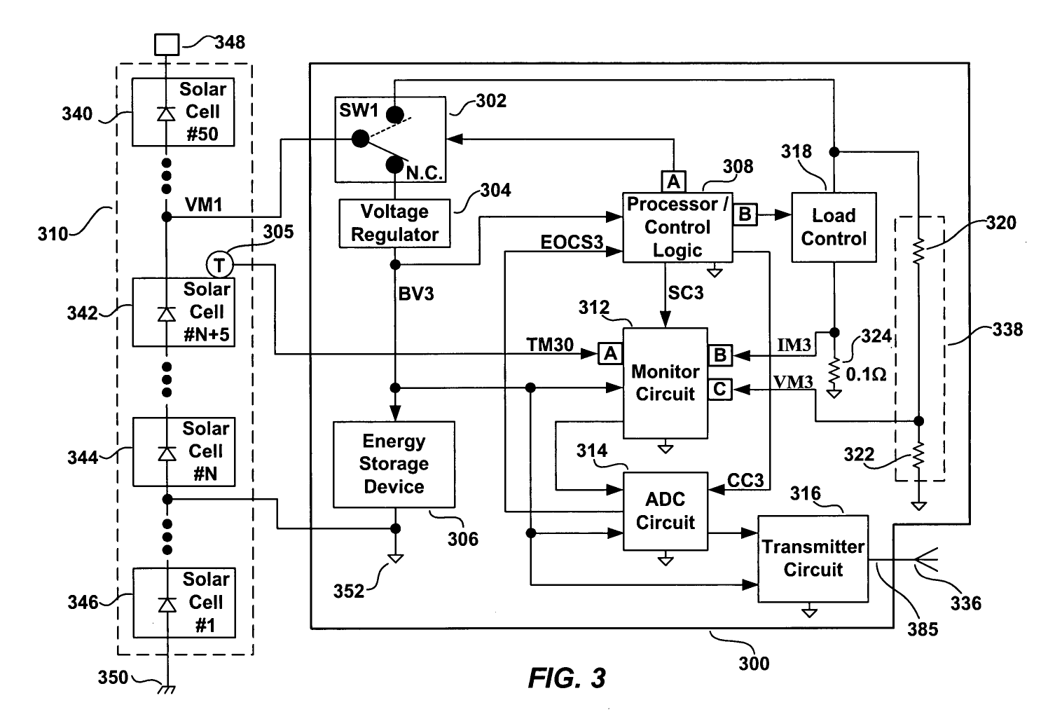

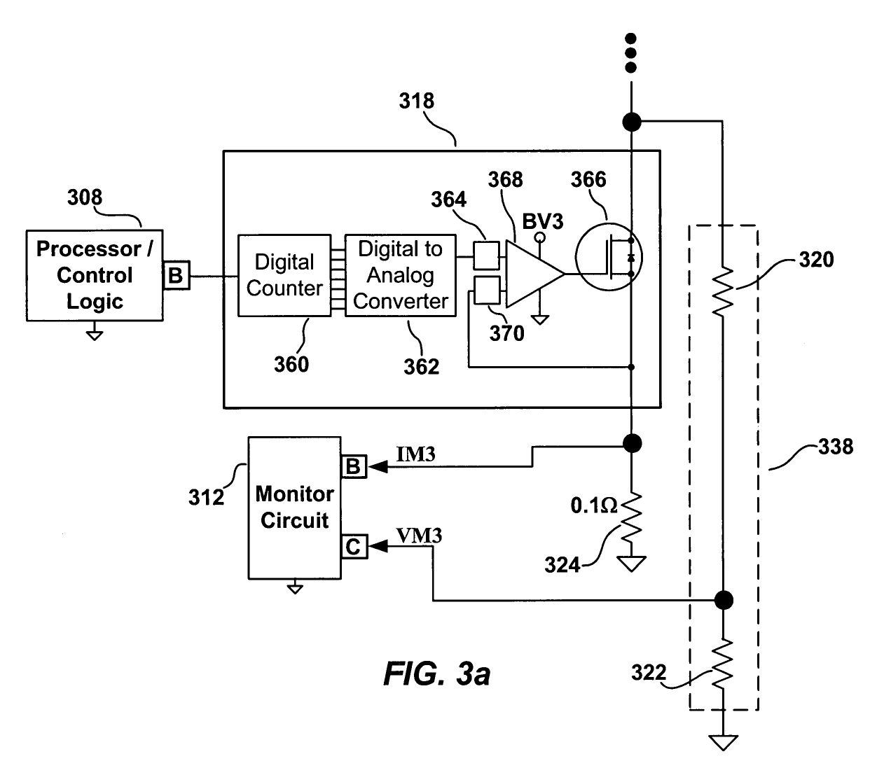

Looking at FIG. 3, a photovoltaic solar health monitoring system is configured to ascertain the health status of a photovoltaic in-situ single string within solar panel 310. Solar panel 310 includes a total of 50 cells.

Within solar panel 310, a single string of six cells, solar cells 344 (#N) through 342 (N+5), are selected for in-situ monitoring as being representative of the health status of solar panel 310. The solar cells, i.e., solar panel devices, are of gallium arsenide (GaAs) construction and yield approximately 2.0 volts per cell when activated by a light source. Alternatively, the cells are of silicon construction, yielding approximately 0.6 volts per cell when activated by a light source. The number of cells selected from the single string generates sufficient voltage to power transmit module 300. As one skilled in the art would recognize, this can be as few as one cell with virtually no upper limit on the maximum, depending upon the design and implementation of the voltage regulator as a boost or buck (step-up or step down) circuit.

For the example of FIG. 3, the single string of six GaAs cells generates a relative voltage of approximately twelve volts across the string to power transmit module 300.

Additionally, solar panel 310 generates approximately 100 volts at solar panel output node 348 to power other functions of the desired solar panel application.

Referring further to FIG. 3, operation of the monitor function of transmit module 300 is now described. The anode of solar cell 348 is connected to solar panel ground 350. PV solar cells within solar panel 310 are activated by photon energy from a light source (not shown). Transmit module ground 352 is created at the anode of solar cell 344, the first cell of the in-situ portion of the single string to be monitored. Voltage output VM1 of the in-situ single string of solar cells appears at the cathode of solar cell 342 and is coupled to normally closed switch 302 of transmit module 300. During standard operation of the solar panel, i.e., not during the health monitoring period, switch SW1 302 is In the normally closed position and voltage VM1 is coupled to the input of voltage regulator 304 to produce regulator output bias voltage BV3. Bias voltage BV3 serves to charge energy storage device 306 which in turn provides power to monitoring circuitry processor/control logic 308, monitor circuit 312, ADC circuit 314, and transmitter circuit 316. Energy storage device 306 is a rechargeable battery. Alternatively, the energy storage device is, but is not limited to, a capacitor.

As one skilled in the art would recognize, processor/control logic 308 can be designed to disable all other functions of the monitoring circuitry to minimize power consumption from the in-situ string/cells in order to minimize the electrical load on the in-situ string/cells during non-health monitoring periods.

During the health monitoring mode, processor/control logic commands switch SW1 302 to the normally open position via control output A and initiates control of load control circuit 318 via output B. Output voltage VM1 of solar panel 310 is redirected to one terminal of the load control circuit and to resistor divider 338. Monitored voltage VM3 is output at the juncture of resistors 320 and 322 of resistor divider 338.

During current monitoring of the health status, resistor 324 is coupled through load control circuit 318 to produce monitored current signal IM3.

Information for IM3 and VM3 is input to monitor circuit 312. The analog output of monitor circuit 312, representing the characteristic of the single in-situ solar cell string, is coupled to the input of conversion ADC circuit 314 for conversion to digital format for further processing by transmitter circuit 316. The transmitter circuit operates in, but is not limited to, an on-off keyed mode. The output of the transmitter is coupled to transmitting antenna 336 at output node 385 for transmission of the information to receiving antenna 16 shown in FIG. 1.

Additionally, transmit module 300 includes temperature sensing capabilities to assure solar cell I-V information is properly correlated to the operating temperature of the solar string. Temperature sensing circuit 305 is mounted near the relevant string of in-situ solar cells within solar panel 310. Specifically in FIG. 3, temperature sensor 305 is mounted adjacent to solar cell 342 and provides temperature sensing information TM30 to input A of monitor circuit 312. Temperature information characteristics are processed further, along with previously mentioned current and voltage information characteristics. Selection of an appropriate temperature sensor is apparent to one skilled in the art.

Processor/control logic 308 further operates with the monitor, conversion and transmit circuits as follows. Processor/control logic 308 instructs monitor circuit 312, via select command signal path SC3, to select the first of the three informations (for a given step), i.e., temperature, voltage, or current, received by the monitor circuit. The respective information is directed to ADC circuit 314. The processor/control logic next instructs the ADC circuit, via convert command signal path CC3, to convert and transmit the resulting information to transmitter circuit 316. Once the ADC has completed transmission of the resulting information, the ADC circuit informs the processor/control logic, via end of convert signal path EOCS3 that the information has been transferred. Processor/control logic 308 then instructs monitor circuit 312 to select the second of the informations, repeating the conversion, end of conversion, and transmit. The process is repeated for the third of the informations.

Thus processor/control logic 308 functions to select transmit module 300 mode of operation, i.e., normal or monitoring, directs loading conditions for the monitored solar component when in the monitoring mode, and directs monitored information for conversion to a suitable signal format for transmission via the transmit module output node 385. The monitored information is transmitted in digital format. Alternatively, the monitored information is transmitted in analog format, for example, but not limited to, a frequency modulated format.

Once health monitoring is complete, processor/control logic 308 directs switch 302 to the normally closed position and redirects voltage VM1 to reinitiate charging of storage device 306 and restores bias voltage BV3, while deactivating the monitoring circuitry.

As one skilled in the art would recognize, implementation of SW1 is accomplished by a number of means including, but not limited to, an electromechanical switch or electronic switch to accomplish the switching function.

Referring to FIG. 3a, further detail of load control circuit 318 is shown. Load control circuit 318 is configured as a linear ramp generator. The load control circuit is arranged with an input coupled to digital counter 360. The parallel output of the digital counter is connected to a digital to analog converter (DAC) 362. The resultant linear stepped-ramp signal output from DAC 362 is supplied to non-inverting input node 364 of amplifier 368.

The duration of the linear stepped ramp signal is, but is not limited to, 1.0 second to provide adequate time to obtain the desired health monitor information.

The duration of the linear stepped ramp signal is, but is not limited to, 1.0 second to provide a short duration period to obtain the desired health monitor data. The duration of the linear stepped ramp is defined so that any change in temperature will not have an appreciable effect on the current—voltage information acquired from the solar cell string under monitor.

The output of amplifier 368 is directed, in turn, to the gate of n-channel transistor 366. The drain-source terminals of n-channel transistor thus present a variable load to the solar cell string that is monitored. The load ranges from Voc (open circuit), i.e., virtually no load current, to Isc, (virtual short circuit) zero voltage condition to the in-situ string of solar cells. The source of the n-channel transistor is coupled to amplifier input node 370 and provides health status monitor current signal information IM3 to input B of monitor circuit 312.

Alternatively, transistor 366 is, but is not limited to, a p-channel transistor or other transistor type known to those skilled in the art.

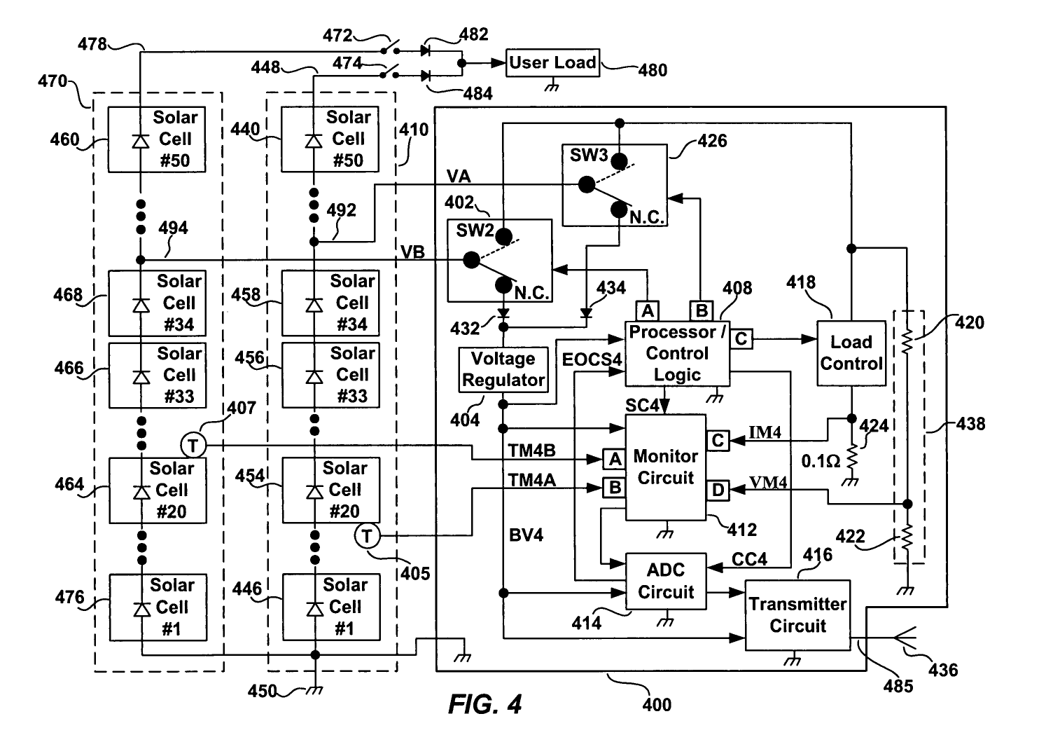

Referring now to FIG. 4, the health status of a solar panel is monitored by sampling two groups of cells, respectively, residing in two solar cell strings in the solar panel.

Solar panel string A 410 and solar panel string B 470 include a total of 50 cells each. The output each of the solar panel strings is correspondingly and respectively coupled through switch 474 and switch 472 and through diodes 482 and 484 to user load 480. Dependent upon user load requirements, switches 472 and 474 select the level of power to be delivered to the load, i.e., solar panel string A 410 or solar panel string B 470 or both strings, or none. Diodes 482 and 484 prevent the flow undesired reverse current into either solar panel string A or solar panel string B.

Solar panel string A 410 contains a monitor string of 34 solar cells within its 50 solar cell total, the monitor string having an output VA at node 492. The monitor string for solar panel A 410 includes solar cell #1 446, solar cell #20 454, solar cell #33 456, and solar cell #34 458. Solar panel string B410 contains a monitor string within its 50 solar cells, the monitor string having an output VB at node 494.

The anode of solar cell #1 446 of solar panel string A and the anode of solar cell #1 476 of solar panel string B are connected to solar panel ground 450.

The solar cells of the solar panels, i.e., solar panel devices, are of gallium arsenide (GaAs) composition and generate a voltage of approximately 2.0 volts per cell when exposed to a light source. Alternatively, the solar cells are, but are not limited to, silicon composition and generate a voltage of 0.6 volts per cell when exposed to a light source.

During normal solar panel string operation, i.e., health monitoring functions inactive, corresponding portions of solar panel string A and solar panel string B provide operating power to transmit module via normally closed switches SW2 402 and SW3 426.

The number of cells selected for each monitored string of the two groups of cells generates sufficient voltage to power transmit module 400. This can be as few as one cell with virtually no upper limit on the maximum, depending upon the design and implementation of the voltage regulator as a boost or buck (step-up or step down) circuit.

As one skilled in the art would recognize, processor/control logic 408 can be designed to disable all other functions of the monitoring circuitry to minimize power consumption from the in-situ string/cells to minimize the electrical load on the in-situ string/cells during non-health monitoring periods.

During health monitoring operation of the system of FIG. 4, when solar cell monitor string A is health monitored at node 492, solar cell monitor string B provides power to transmit module 400 from node 494; and when solar cell monitor string B is health monitored at node 494, solar cell monitor string A provides power to transmit module 400 from node 492.

For example, during the monitoring of the monitor string for solar panel string A, an external control, not shown and not attached to transmit module 400, commands switch 474 to the open position to disconnect the string from any external load permitting the health monitoring system to obtain true Voc information.

Processor/control logic 408 generates a signal at output A that maintains switch SW2 402 in a closed position and generates a signal at output B correspondingly opening switch SW3 426.

With switch SW2 closed, voltage VB at node 494 is coupled through the switch and through diode 432 to provide voltage VB to the input of voltage regulator 404. The voltage regulator regulated output provides couples voltage bias BV4 to power to monitoring circuitry processor/control logic 408, monitor circuit 412, ADC circuit 414, and transmitter circuit 416 during the monitoring process.

With switch SW3 open, processor/control logic 408 initiates control of load control circuit 418 via output C. Output voltage VA of the solar cell monitored string at node 492 is redirected to one terminal of the load control circuit and to resistor divider 438. Monitored voltage VM4 is output at the juncture of resistors 420 and 422 of resistor divider 438.

During current monitoring of the health status, resistor 424 is coupled through load control circuit 318 to produce monitored current signal IM4.

The circuitry used for load control circuit 418 is the same as that shown in detail in FIG. 3a. The duration of the monitor cycle is, but is not limited to, 1.0 seconds. One skilled in the art would ascertain alternate load circuits, alternate timing control of switches SW2 402 and SW3 426, and appropriate timing for initiating the monitoring process.

Information for IM4 and VM4 is input to monitor circuit 412 at monitor input terminals C and D respectively. The analog output of monitor circuit 412, representing the characteristic of the solar monitored cell string from solar panel string A 410, is coupled to the input of conversion ADC circuit 414 for conversion to digital format for further processing by transmitter circuit 416. The transmitter circuit operates in, but is not limited to, an on-off keyed mode. The output of the transmitter is coupled to transmitting antenna 436 at output node 485 for transmission of the information to receiving antenna 16 shown in FIG. 1.

Additionally, transmit module 400 includes temperature sensing capabilities to assure solar cell I-V information is properly correlated to the operating temperature of the solar string. Temperature sensing circuit 405 is mounted near the relevant string of monitored solar cells within solar panel string A 410. Specifically in FIG. 4, temperature sensor 405 is mounted adjacent to solar cell 454 and provides temperature sensing information TM4A to input B of monitor circuit 412. Temperature information characteristics are processed further, along with previously mentioned current and voltage information characteristics.

Processor/control logic 408 further operates with the monitor, conversion and transmit circuits as follows. Processor/control logic 408 instructs monitor circuit 412, via select command signal path SC4, to select the first of the three informations (for a given step), i.e., temperature, voltage, or current, received by the monitor circuit. The respective information is directed to ADC circuit 414. The processor/control logic next instructs the ADC circuit, via convert command signal path CC4, to convert and transmit the resulting information to transmitter circuit 416. Once the ADC has completed transmission of the resulting information, the ADC circuit informs the processor/control logic, via end of convert signal path EOCS4 that the information has been transferred. Processor/control logic 408 then instructs monitor circuit 412 to select the second of the informations, repeating the conversion, end of conversion, and transmit. The process is repeated for the third of the informations.

Thus processor/control logic 408 functions to select transmit module 400 mode of operation, i.e., normal or monitoring, directs loading conditions for the monitored solar component when in the monitoring mode, and directs monitored information for conversion to a suitable signal format for transmission via the transmit module output node 485. The monitored information is transmitted in digital format. Alternatively, the monitored information is transmitted in analog format, for example, but not limited to, a frequency modulated format.

Likewise, for solar cell monitoring string B (monitoring node 494) of solar panel string B 470, temperature sensor 407 is located adjacent to solar cell #20 464 to provide temperature information to input terminal A of monitor circuit 412 during health monitoring for solar cell string B.

Selection of appropriate temperature sensors is apparent to one skilled in the art.

Once health monitoring of solar cell monitor string A is complete, processor/control logic 408 directs switch sw3 426 to the normally closed position and restores normal operation to the solar panel system.

Referring again to FIG. 4, the circuit is programmed to operate, for example, in a ping-pong mode, i.e., transmit module 400 alternately monitors the health of solar panel string A 410 and the health of solar panel string B 470.

Upon completion of the monitor cycle as described previously for FIG. 4 and prior to restoring normal operation to the solar panel system, processor/control logic 408 generates a signal at output A commanding switch SW2 402 to an open position and generates a signal at output B correspondingly closing switch SW3 426.

As one skilled in the art would recognize, implementation of SW2 and SW3 is accomplished by but not limited to, electromechanical switches or electronic switches.

Monitoring of the health status is switched to solar cell monitor string B of solar panel string B at node 494, and solar cell string A of solar panel string A 410 now provides power to transmit module 400 from node 492.

Transmit module 400 operates as follows.

With switch SW3 426 closed, voltage VA at node 492 is coupled through the switch and through diode 434 to provide voltage VA to the input of voltage regulator 404. The voltage regulator regulated output provides couples bias voltage BV4 to power to monitoring circuitry processor/control logic 408, monitor circuit 412, ADC circuit 414, and transmitter circuit 416 during the monitoring process.

With switch SW2 open, processor/control logic 408 initiates control of load control circuit 418 via output C. Output voltage VB of the solar cell monitored string at node 494 is redirected to one terminal of the load control circuit and to resistor divider 438. Monitored voltage VM4 is output at the juncture of resistors 420 and 422 of resistor divider 438.

During current monitoring of the health status, resistor 424 is coupled through load control circuit 318 to produce monitored current signal IM4.

The duration of the monitor cycle is, but is not limited to, 1.0 seconds. One skilled in the art would ascertain alternate load circuits, alternate timing control of switches SW2 402 and SW3 426, and appropriate timing for initiating the monitoring process.

Information for IM4 and VM4 is input to monitor circuit 412 at monitor input terminals C and D respectively. The analog output of monitor circuit 412, representing the characteristic of the solar monitored cell string from solar panel string A 410, is coupled to the input of conversion ADC circuit 414 for conversion to digital format for further processing by transmitter circuit 416. The output of the transmitter is coupled to transmitting antenna 436 for transmission of the information to receiving antenna 16 shown in FIG. 1.

Additionally, transmit module 400 includes temperature sensing capabilities to assure solar cell I-V information is properly correlated to the operating temperature of the solar string. Temperature sensing circuit 407 is mounted near the relevant string of monitored solar cells within solar panel string A 410. Specifically in FIG. 4, temperature sensor 407 is mounted adjacent to solar cell 464 and provides temperature sensing information TM4B to input A of monitor circuit 412.

Once health monitoring of solar cell monitor string B is complete, processor/control logic 408 directs switch SW3 426 to the normally closed position and restores normal operation to the solar panel system. Alternatively, processor/control logic 408 directs the system to continue to operate in the ping-pong mode.

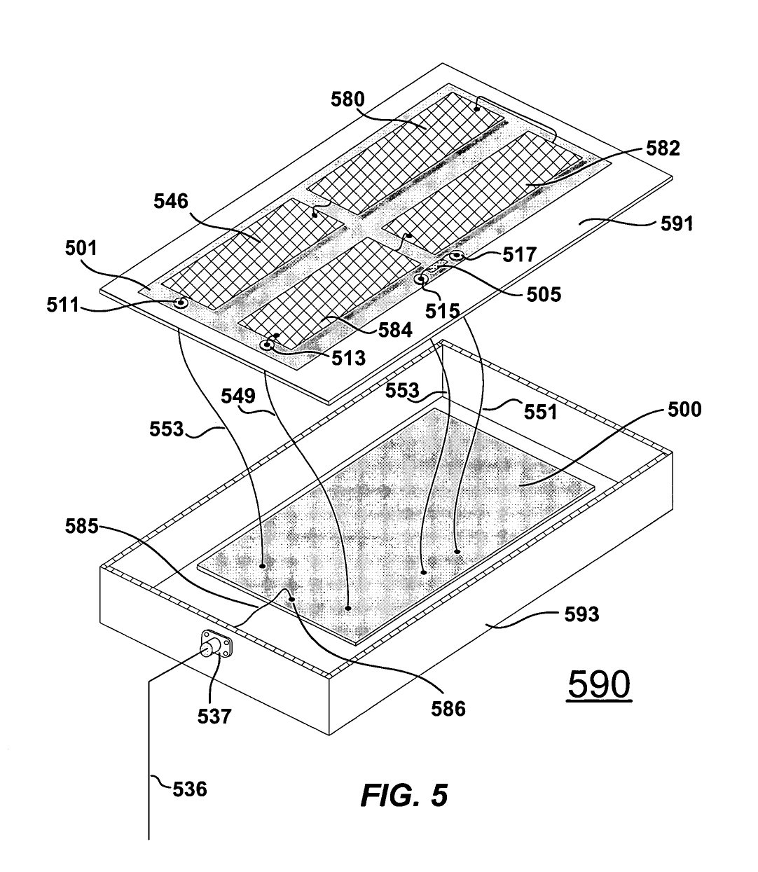

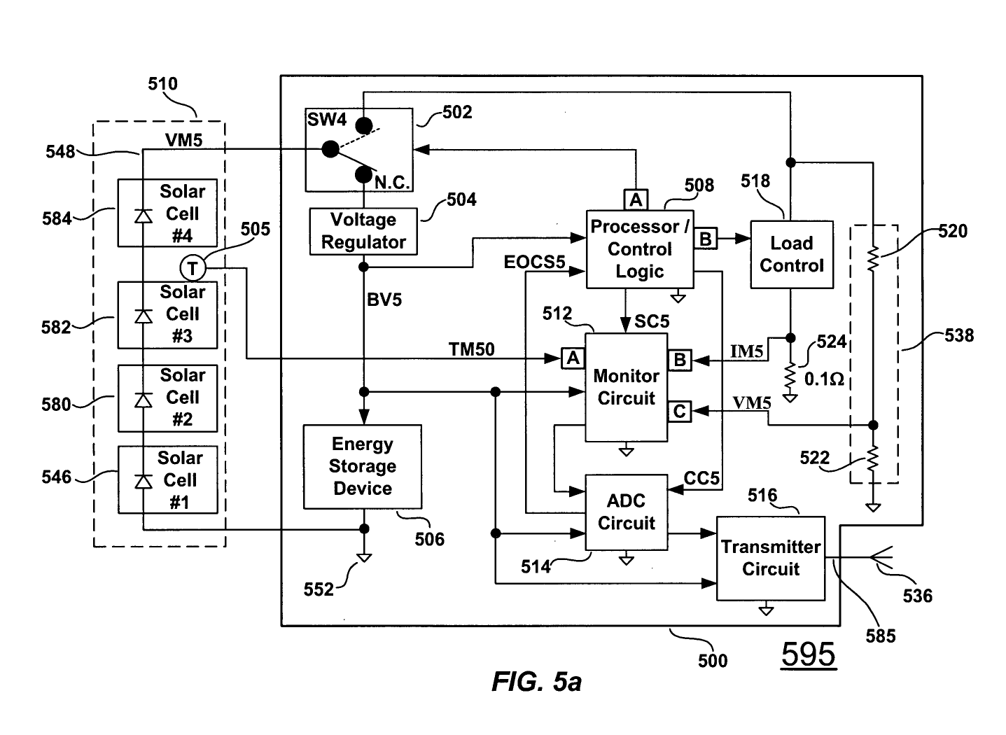

Referring now to FIG. 5, dedicated transmit module 590 is shown. Dedicated transmit module 590 serves as a single package, self powered device for a photovoltaic solar array health monitor. The dedicated transmit module is inserted, attached, or mounted within, or adjacent to, a solar panel, array, string, or cell to provide a stand alone, self powered health monitor system for the respective solar panel, array, string, or cell. The PV health monitor integrates a solar string, a transmit module, and an antenna. Detail of circuitry elements housed on and within dedicated transmit module 590 are referenced in FIG. 5a.

In FIG. 5, solar cells 546, 580, 582, and 584, and temperature sensor 505 are mounted to non-conductive solar string substrate 501. The solar cells are connected in an anode to cathode fashion as shown in FIG. 5a with the anode of cell 546 connected via wire 553 to node 552 and the cathode connected via wire 549 to node 548.

Temperature senor 505 is attached to solar substrate 501 and is connected to transmit module 500 of FIG. 5a via wires 551 and 553.

Solar string substrate 501 is attached to conductive dedicated module lid 591. Methods of cell and temperature sensor mounting and substrate attachment are, but not limited to, epoxy based glue.

Isolating feed-throughs 511, 513, 515, and 505 prevent the shorting of wires 553, 549, 553, and 551 to the conductive lid of the module.

Dedicated transmit module housing 593 is, but not limited to, metal construction and serves to house transmit module 500. Transmit module 500 is attached, for example, to a printed circuit board which in turn is affixed to dedicated transmit module housing 593 using epoxy based glue. Alternatively, the transmit module may float within the housing, mount in a potting compound within the module housing, or attached by other methods to those known by those skilled in the art.

Antenna wire 586 connects node 586 of FIG. 5a to transmit antenna connector 537 mounted on housing 593. Transmit antenna 536 is connected to the antenna connector. Alternatively, the transmit antenna may be implemented actively, but not limited to, as the metallic module housing, in part or in total, or as a circuit trace on the transmit module printed circuit board (not shown) or as a circuit trace on a module housing or module lid.

Dedicated module lid is welded to dedicated transmit module housing 593 to form the total package housing. Alternatively, the lid is attached using epoxy glue, compression fit, brazing, and other methods known to those skilled in the art.

Alternatively, dedicated module lid and dedicated transmit module housing are fabricated from non-conductive materials.

Referring now to FIG. 5a, dedicated transmit module electronics 595 is configured for compatibility with the package device described in FIG. 5.

Looking at FIG. 5a, a monitoring system is configured to ascertain the health status of a dedicated photovoltaic string within solar panel 510. Solar panel 510 includes a total of four cells, solar cell #1 546, solar cell #2 580, solar cell #3 582, and solar cell #4 584.

Solar panel 510 and transmit module 500 are packaged within the same assembly to facilitate a dedicated module. The module is installed, for example, within a solar panel array, not shown, to provide sampled information as to the status of the solar panel. Upon exposure to a light source, solar cell #1 546, solar cell #2 580, solar cell #3 582, and solar cell #4 584 generate a voltage VM5 at node 548.

The solar cells, i.e., solar panel devices, are of gallium arsenide (GaAs) construction and yield approximately 2.0 volts per cell when activated by a light source. Alternatively, the cells are of silicon construction, yielding approximately 0.6 volts per cell when activated by a light source. The number of cells selected dedicated string generates sufficient voltage to power transmit module 300. As one skilled in the art would recognize, this can be as few as one with virtually no upper limit on the maximum, depending upon the design and implementation of voltage regulator 504 as a boost or buck (step-up or step down) circuit.

Referring further to FIG. 5a, operation of the monitor function of transmit module 500 is now described. The anode of solar cell 546 is connected to circuit ground 552. Transmit module utilizes the same circuit ground 552 reference, thus providing a common ground for the system. Once PV solar cells within solar panel 510 are activated by photon energy from a light source, voltage output VM5 of the dedicated single string of solar cells appears at the node 548 and is coupled to normally closed switch SW1 502 of transmit module 500. During the period where health monitoring is not in effect, switch SW1 502 is In the normally closed position and voltage VM5 is coupled to the input of voltage regulator 504 to produce regulator output bias voltage BV5. Bias voltage BV5 serves to charge energy storage device 506 which in turn provides power to monitoring circuitry processor/control logic 508, monitor circuit 512, ADC circuit 514, and transmitter circuit 516. Energy storage device 506 is a rechargeable battery. Alternatively, the energy storage device is, but is not limited to, a capacitor.

During the health monitoring mode, processor/control logic commands switch 502 to the open position via output A and initiates control of load control circuit 518 via output B. Output voltage VM5 of solar panel 510 is redirected to one terminal of the load control circuit and to resistor divider 538. Monitored voltage VM5 is output at the juncture of resistors 520 and 522 of resistor divider 538.

During current monitoring of the health status, resistor 524 is coupled through load control circuit 518 to produce monitored current signal IM5.

Information for IM5 and VM5 is input to monitor circuit 512. The analog output of monitor circuit 512, representing the characteristic of the dedicated single solar cell string, is coupled to the input of conversion ADC circuit 514 for conversion to digital format for further processing by transmitter circuit 516. The transmitter circuit operates in, but is not limited to, an on-off keyed mode. The output of the transmitter is coupled to transmitting antenna 536 at output node 585 for transmission of the information to a receiving antenna (not shown).

Additionally, transmit module 500 includes temperature sensing capabilities to assure solar cell I-V information is properly correlated to the operating temperature of the solar string. Temperature sensing circuit 505 is mounted near the relevant string of dedicated solar cells within solar panel 510. Specifically in FIG. 5a, temperature sensor 505 is mounted adjacent to solar cell 582 and provides temperature sensing information TM50 to input A of monitor circuit 512. Temperature information characteristics are processed further, along with previously mentioned current and voltage information characteristics. Selection of an appropriate temperature sensor is apparent to one skilled in the art.

Processor/control logic 508 further operates with the monitor, conversion and transmit circuits as follows. Processor/control logic 508 instructs monitor circuit 512, via select command signal path SC5, to select the first of the three informations (for a given step), i.e., temperature, voltage, or current, received by the monitor circuit. The respective information is directed to ADC circuit 514. The processor/control logic next instructs the ADC circuit, via convert command signal path CC5, to convert and transmit the resulting information to transmitter circuit 516. Once the ADC has completed transmission of the resulting information, the ADC circuit informs the processor/control logic, via end of convert signal path EOCS5 that the information has been transferred. Processor/control logic 508 then instructs monitor circuit 512 to select the second of the informations, repeating the conversion, end of conversion, and transmit. The process is repeated for the third of the informations.

Thus processor/control logic 508 functions to select transmit module 500 mode of operation, i.e., normal or monitoring, directs loading conditions for the monitored solar component when in the monitoring mode, and directs monitored information for conversion to a suitable signal format for transmission via the transmit module output node 585. The monitored information is transmitted in digital format. Alternatively, the monitored information is transmitted in analog format, for example, but not limited to, a frequency modulated format.

Once health monitoring is complete, processor/control logic 508 directs switch SW4 502 to the normally closed position and redirects voltage VM5 to reinitiate charging of storage device 506 and restores bias voltage BV5, while deactivating the monitoring circuitry.

Thus, it can now be appreciated that the present invention provides a monitoring system module that is efficiently constructed to monitor the health of a PV solar cell string.

It can be further appreciated that the present invention provides a monitoring system module that is efficiently constructed to monitor the health of a dedicated string of solar cells packaged and integrated in conjunction with the monitoring system.

It can be even further appreciated that the dedicated monitoring system can be installed within a larger solar array to reflect the health condition of the solar array.

It can be even more so appreciated that the present invention can be applied for monitoring the health of a single cell or the health of a solar cell panel.

It can be still further appreciated that the present invention can operate in an in-situ monitoring mode while deriving power from the monitored solar cell or cells.

It can be even still further appreciated that the present invention operates in a self-powering mode.

While specific embodiments of the present invention have been shown and described, further modifications and improvements will occur to those skilled in the art. It is understood that the invention is not limited to the particular forms shown, and it is intended for the appended claims to cover all modifications that do not depart from the spirit and the scope of this invention.

We claim:

1. A photovoltaic solar health monitor comprising:
a transmit module having an input coupled for receiving a signal from a solar panel device and an output coupled for transmitting health status information, said transmit module comprising,
a switch having an input coupled to said transmit module input, said switch having a first output position coupled to a bias circuit and having a second output position coupled to a load,
said bias circuit configured for supplying a voltage to said transmit module;
a processor/control means having a controlling first output controllably coupled to said switch for commanding a mode of operation of said transmit module, said mode being a normal mode when said switch is in said first output position, and said mode being a monitoring mode when said switch is in said second output position;
a load control device having an input coupled to a controlling second output of said processor/control means for receiving a load control signal, said load control device having first and second terminals for coupling said load to said input of said transmit module during said monitoring mode;
a monitoring circuit having first and second inputs coupled to first and second outputs, respectively, of said load control device for receiving a plurality of informations from said load control device,
said monitoring circuit having a third input coupled for receiving a controlling signal from a controlling third output of said processor/control means to select one of said plurality of informations, and
said monitoring circuit having an output for outputting said one of said plurality of informations;
a conversion circuit having a first input coupled to said output of said monitor circuit for converting said informations from a first format to a second format; and having a second input coupled to a fourth output of said processor/control means for synchronizing said load control signal with said informations;
a transmitter circuit having an input coupled to said output of said conversion circuit, said transmitter circuit having an output configured for transmitting said second formatted informations.

2. The photovoltaic solar health monitor of claim 1, wherein said bias circuit is a voltage regulator.

3. The photovoltaic solar health monitor of claim 1, further comprising a storage element coupled to said transmit module input and configured to provide power during said monitoring mode.

4. The photovoltaic solar health monitor of claim 3, wherein said storage element is a capacitor.

5. The photovoltaic solar health monitor of claim 3, wherein said storage element is a rechargeable battery.

6. The photovoltaic solar health monitor of claim 1, further comprising an antenna coupled to said output of said transmitter circuit, wherein said antenna, said solar panel device, and said transmit module are integrated as a single package.

7. The photovoltaic solar health monitor of claim 6, wherein said antenna is part of a package housing.

8. The photovoltaic solar health monitor of claim 6, wherein said package housing is conductive.

9. The photovoltaic solar health monitor of claim 1, wherein said solar panel device is a single cell.

10. The photovoltaic solar health monitor of claim 1, wherein said monitor includes a fourth input coupled for receiving temperature sensor information from a temperature sensor output.

11. The photovoltaic solar health monitor of claim 1, wherein said transmitter circuit output is configured as an on-off keyed output.

12. The photovoltaic solar health monitor of claim 1, wherein said transmitter circuit output is configured as a sonic output.

13. The photovoltaic solar health monitor of claim 1, wherein said transmitter circuit output is configured as an optical output.

14. A method of determining the health of a photovoltaic solar panel, comprising the steps of:
a) selecting a bias mode of operation;
b) selecting a monitoring mode of operation;
c) alternating between said bias mode of operation and said monitoring mode of operation;
d) applying a common bias from an originating source,
1) removing said originating source during said monitoring mode; and
e) loading the solar panel during the monitoring mode to generate health status information,
1) processing said health status information,
2) communicating said health status information.

15. A photovoltaic solar health monitor comprising:
a transmit module having a first input coupled for receiving a signal from a first solar panel device, a second input coupled for receiving a signal from a second solar panel device and an output coupled for transmitting health status information of said first and second solar panel devices, said transmit module comprising,
a first switch having an input coupled to said transmit module first input, said first switch having a first output position coupled to a bias circuit and having a second output position coupled to a load;
a second switch having an input coupled to said transmit module second input, said second switch having a first output position coupled to said bias circuit and having a second output position coupled to said load;
a processor/control means having controlling first output coupled to said first switch for commanding a mode of operation of said transmit module, and having a second output controllably coupled to said second switch for commanding said mode of operation of said transmit module,
wherein said mode is a normal mode when said first and second switches in said first output position,
wherein said mode is in a first monitoring mode when said first switch is in said second output position and said second switch is in said first output position, and
wherein said mode is in a second monitoring mode when said first switch is in said first output position and said second switch is in said second output position,
wherein said processor/control means is configured to operate alternately between said first monitoring mode and said second operating mode;
a load control device having an input coupled to a controlling third output of said processor/control means for receiving a load control signal, said load control device having first and second terminals for coupling said load coupled to said first and second inputs of said transmit module during said first and second monitoring modes respectively;
a monitoring circuit having first and second inputs coupled to first and second outputs, respectively, of said load control device for receiving a plurality of informations from said load control device,
said monitoring circuit having a third input coupled for receiving a controlling signal from a controlling fourth output of said processor/control means to select one of said plurality of informations, and
said monitoring circuit having an output for outputting said one of said plurality of informations;
a conversion circuit having a first input coupled to said output of said monitor circuit for converting said informations from a first format to a second format; and having a second input coupled to a fifth output of said processor/control means for synchronizing said load control signal with said informations; and
a transmitter circuit having an input coupled to said output of said conversion circuit, said transmitter circuit having an output configured for transmitting said second formatted informations.

16. The photovoltaic solar health monitor of claim 15, wherein said first solar panel device is a single cell.

17. The photovoltaic solar health monitor of claim 15, wherein said monitor includes a fourth input coupled for receiving temperature sensor information from a temperature sensor output.

18. The photovoltaic solar health monitor of claim 15, wherein said transmitter circuit output is configured as an on-off keyed output.

19. The photovoltaic solar health monitor of claim 15, wherein said transmitter circuit output is configured as a sonic output.

20. The photovoltaic solar health monitor of claim 15, wherein said transmitter circuit output is configured as an optical output.
